(19) United States
(12) Patent Application Publication
(10) Pub. No.: US 2015/0064394 A1
(43) Pub. Date: Mar. 5, 2015

(54) COMPUTING DEVICE COVER

(71) Applicants: Paul Gwin, Orangevale, CA (US); Mark Sprenger, Folsom, CA (US)

(72) Inventors: Paul Gwin, Orangevale, CA (US); Mark Sprenger, Folsom, CA (US)

(21) Appl. No.: 14/014,782

(22) Filed: Aug. 30, 2013

(51) Int. Cl. H05K 5/03; B29C 45/16; H05K 5/00; B29D 99/00

(52) U.S. Cl. CPC H05K 5/03; B29D 99/006; B29C 45/16; H05K 5/0086; B29K 2101/00
USPC 428/116; 264/279; 428/457; 428/307.3; 428/172; 428/138

(57) ABSTRACT

Techniques for forming portions of a computing device are described herein. The techniques include a method including forming a first portion of a computing device, the first portion composed of a metal. A nanostructure layer of the first portion is formed, and a second portion of the computing device is formed, wherein the second portion composed of a polymer. The method includes coupling the first portion to the second portion by injection molding the polymer of the second portion onto the nanostructure layer.

### TECHNICAL FIELD

This disclosure relates generally to techniques for forming portions of a computing device. More specifically, the disclosure describes techniques for increasing platform stiffness using a support structure molded to a back cover of the computing device.

### BACKGROUND

With the fast growth of computing devices, lighter, thinner computing devices are increasingly preferred by users. Platform stiffness may affect usability, reliability, and perceived quality while also preventing stress of various components.

### BRIEF DESCRIPTION OF DRAWINGS

FIG. 1 is a perspective view of a support structure to be coupled to a cover of a computing device.

FIG. 2 is a perspective view of an exterior side of a bottom cover.

FIG. 3 is a top view of an interior side of the bottom cover formed with integration features.

FIG. 4 is a cross-sectional view of the nanostructure layer.

FIG. 5 is a top view of the cover formed with a support structure.

FIG. 6 is a perspective view of a portion of the support structure defining holes in the support structure.

FIG. 7 is a block diagram illustrating a method of forming a cover having a support structure.

### DETAILED DESCRIPTION

The subject matter disclosed herein relates to techniques for increasing platform stiffness. A computing device may be configured having portions, such as a bottom cover. A nanostructured layer may be applied to an interior side of the cover. For example, the nanostructured layer may be applied to the interior side of the cover using a thermoset thermoplastic adhesive primer. Method and systems described herein relate to coupling a support structure to the cover by injection molding the support structure to the nanostructure layer.

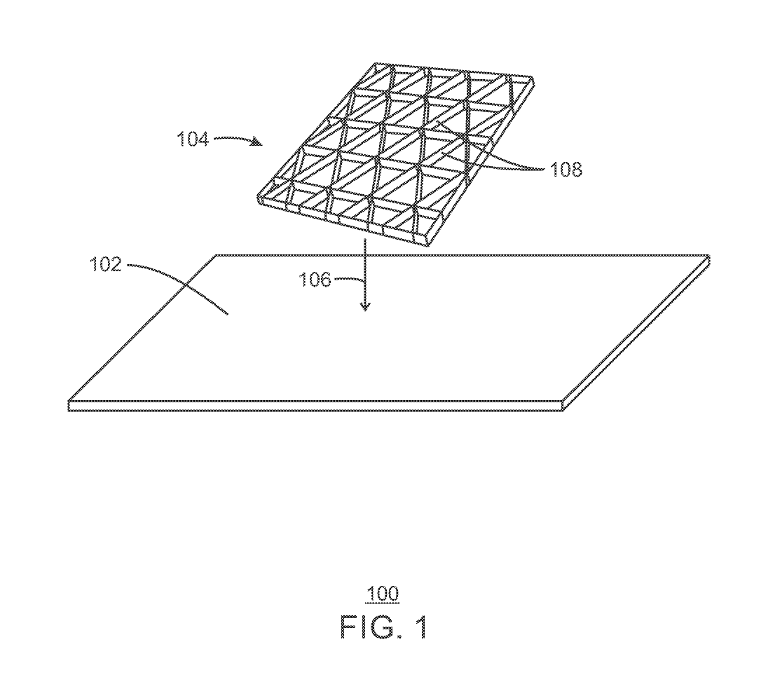

FIG. 1 is a perspective view of a support structure to be coupled to a cover of a computing device. The computing device (not shown) may be laptop computer, a desktop computer, a tablet computing device, a mobile computing device, an all-in-one (AIO) computing device, a smart phone computing device, and the like. The cover 102 may be a bottom cover of the computing device configured to receive a support structure 104 as indicated by the arrow 106. The cover 102 may be a monolithic clad metal component having a nanostructure oxide layer applied to the cover 102. The nanostructure oxide layer may be configured to receive the support structure 104 by injection molding described in more detail below.

The support structure 104 may be configured as a grid structure having stiffening ribs 108, such as an isotropic grid (isogrid) having stiffening ribs in a triangular pattern as illustrated in FIG. 1. Although illustrated in FIG. 1 as having a triangular pattern, other patterns such as ax hex cell patterns, circle patterns, square patterns may be used. In embodiments, the stiffening ribs may be perturbed such that the support structure 104 may accommodate additional components of a computing device as discussed in more detail below. The support structure 104 may be composed of a polymer suitable for injection molding onto the nanostructure layer. Suitable polymers may include polyethylene terephthalate (PET), polydioxanone (PDO), nylon, polyphenylene sulfide (PPS), and the like. In embodiments, the polymer of the support structure 104 may incorporate strengthening material such as glass, aramid, carbon, polymer fibers of relatively high glass transition temperature (Tg) in relation to the polymer used to form the support structure 104.

An increase in stiffness of the cover 102 may be a function of the thickness of the cover 102. The support structure 104 being coupled to the cover 102 may increase stiffness of the cover 102, without necessarily increasing the thickness of the cover 102. An increase in cover stiffness may result in relatively higher performance of components of the computing device, reliability, and perceived quality.

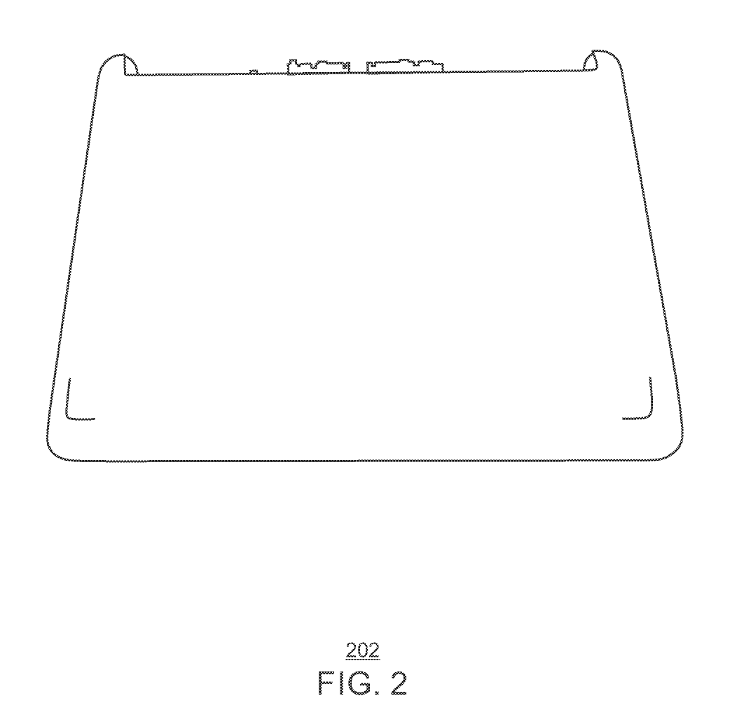

FIG. 2 is a perspective view of an exterior side of a bottom cover. The bottom cover 202 may be formed as a monolithic metal clad cover. In embodiments, the cover 202 is composed of a metal, such as aluminum, suitable for receiving a nanostructured oxide. In other embodiments, the cover 202 is composed of a non-aluminum metal such as stainless steel, titanium, or other metal configured to receive the nanostructured oxide layer using a thermoset thermoplastic adhesive primer.

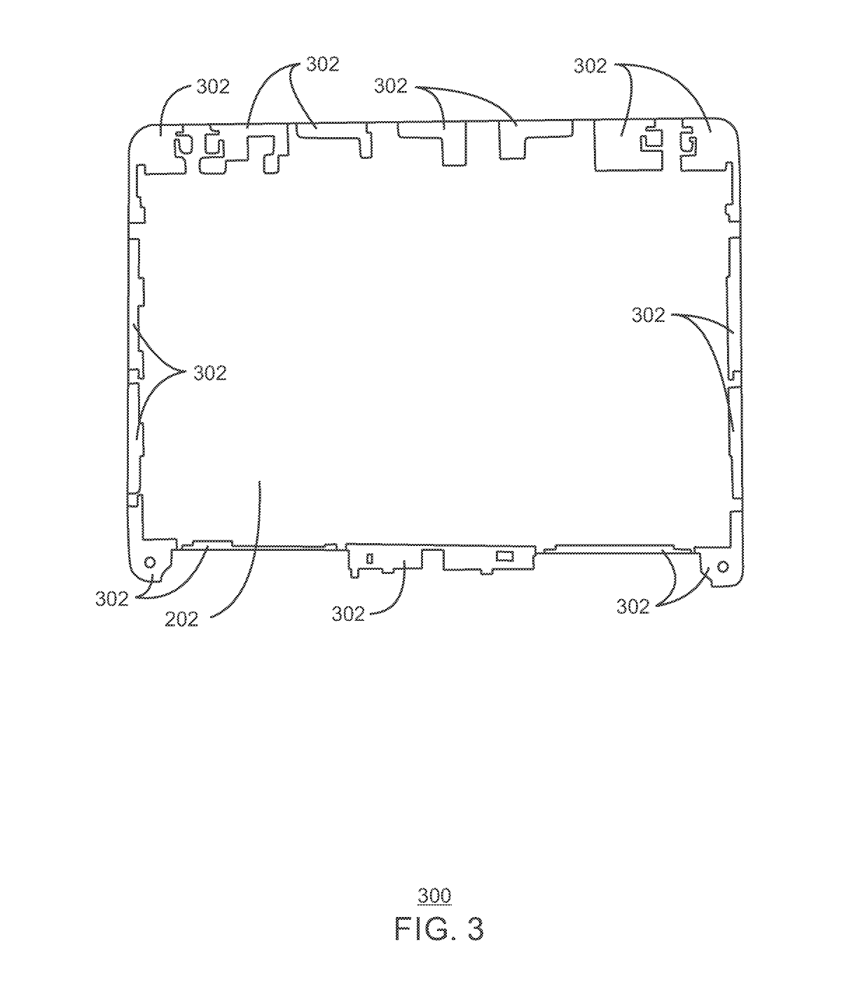

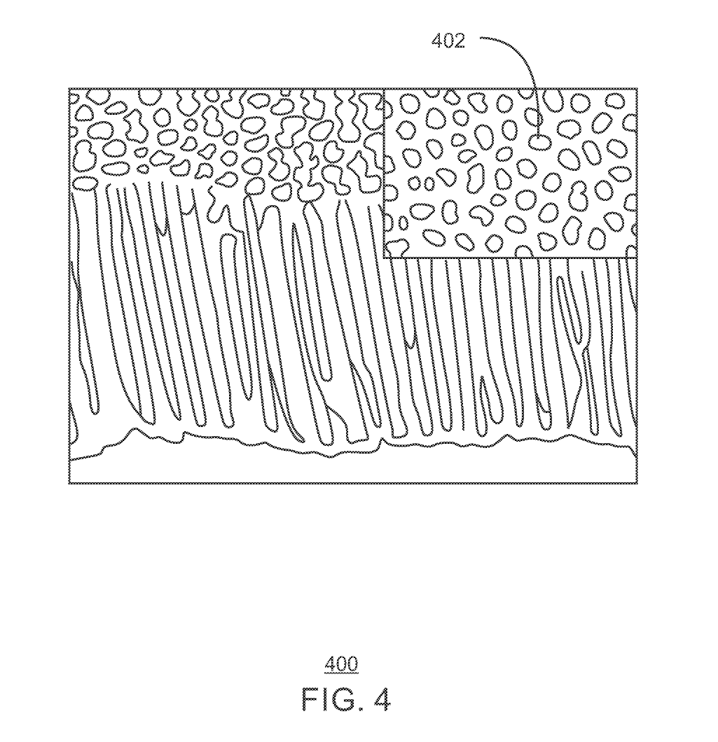

FIG. 3 is a top view of an interior side of the bottom cover formed with integration features. The integration features 302 are configured to receive components (not shown) of the computing device such as a processor, memory units, storage units, network interfaces, and the like. In embodiments, the integration features 302 may be coupled to the interior side of the bottom cover 202 by injection molding. For example, the integration features 302 may be composed of a polymer, similar to the polymer of the support structure 104 discussed above in reference to FIG. 1. The integration features 302 may be injection molded onto the nanostructure oxide layer discussed in more detail below in reference to FIG. 4. In embodiments, the integration features 302 and the support structure 104 may be simultaneously coupled to the bottom cover 202 by injection molding onto the nanostructure oxide layer.

FIG. 4 is a cross-sectional view of the nanostructure layer. As illustrated in FIG. 4, the nanostructure oxide layer 400 defines pores 402. The pores 402 may be configured to at least partially receive the polymer of the support structure 104 discussed above in reference to FIG. 1, the polymer of the integration features 302 discussed above in reference to FIG. 3, or any combination of the polymers of the support structure 104 and the integration features 302.

In embodiments, the nanostructured oxide layer 400 may be formed by growing an oxide in an anodic process. Specific geometries of the pores 402 in the nanostructured oxide layer 400 are achieved as desired by variation of an electrolyte pH and an anodic voltage. Variations of these processes are capable of producing a range of ordered nanostructured pores, such as the pores 402, having a range of pore diameters (such as 5 nm to 10 um). In embodiments, the nanostructured oxide layer 400 may be formed on a relatively thin and pure (99.99% +) aluminum face of the aluminum sheet which is cladded to a base aluminum alloy of the cover 202 discussed above. In other embodiments, the nanostructured oxide layer 400 may be formed directly on lower purity forms of aluminum (99%) using differing techniques and different combinations of pH, acid type, molarity, and anodic voltage to control nucleation sites. Other commercially available techniques beyond the techniques described above of forming a nanostructured oxide to a metal may be used.

In embodiments, the pores 402 are configured to have a height to enable for adequate adhesion with the polymer of the support structure 104 discussed above in reference to FIG. 1. In embodiments, the height of the pores 402 is proportional to the anodic voltage used in forming the nanostructure oxide layer 400, wherein increases in anodic voltage is proportional to an increase in the height of the pores 402. The height of the pores 402 may be configured such that a surface area of the polymer of the support structure 104 may be received within the pores 402, thereby coupling the support structure 104 to the cover 202 discussed above in reference to FIGS. 1, 2, and 3.

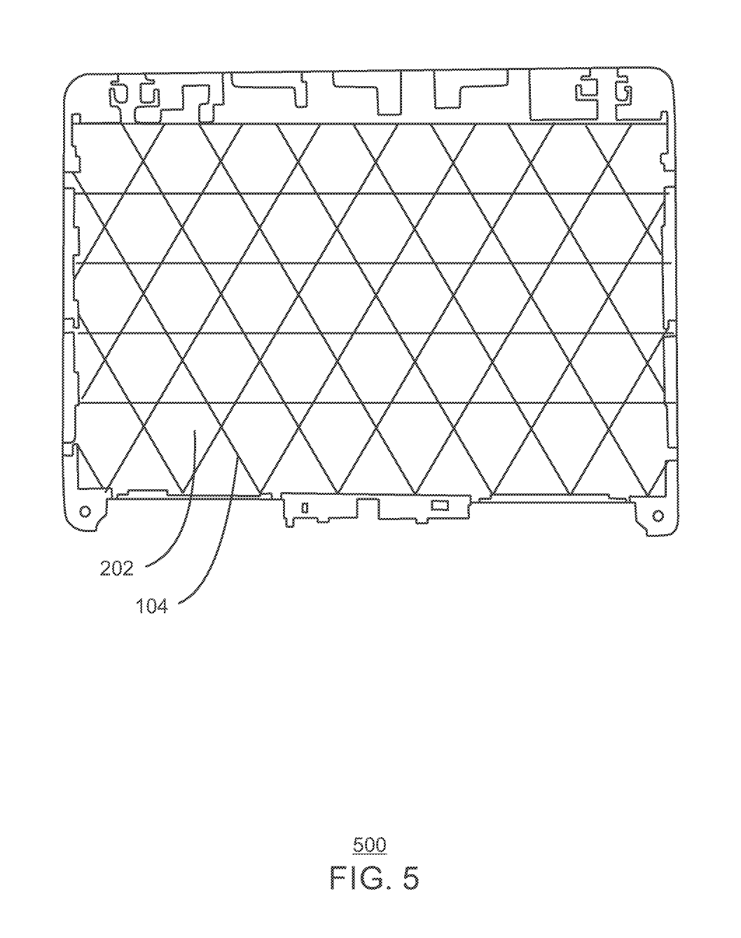

FIG. 5 is a top view of the cover formed with a support structure. As illustrated in FIG. 5, the support structure 104 may be comprised of stiffening components such as stiffening ribs. The support structure 104, being composed of a polymer, may be coupled to the nanostructured oxide layer 400 discussed above in reference to FIG. 4. Although FIG. 5 illustrates a support structure 104 having triangular stiffening ribs, the stiffening ribs may be formed in various shapes, including circular, semi-circular, rectangular, hexagonal, honeycomb, and the like. The stiffening provided by the support structure may increase the overall stiffness of the bottom cover 202, without increasing the amount of metal used to form the bottom cover 202.

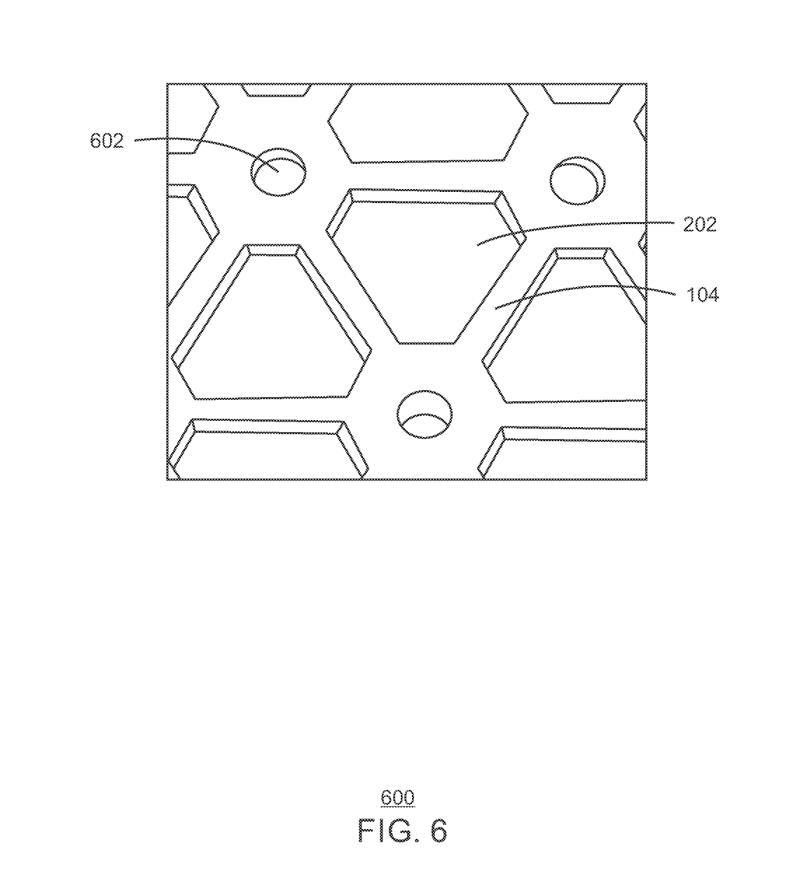

FIG. 6 is a perspective view of a portion of the support structure defining holes in the support structure. In embodiments, the support structure 104 may define a hole 602 configured to receive a fastener (not shown). The support structure 104 may be configured to enable components to be coupled to the support structure. For example, the support structure may be configured to receive components such as processing devices, memory devices, network interfaces, and the like. In embodiments, the height of the support structure 104 extending normal to the bottom cover 202 may be uniform across the support structure 104. In embodiments, the height of the support structure 104 may be varied such that a given component of the computing device may be received into a relatively low portion of the support structure 104 in relation to relatively higher portions of the support structure 104. For example, the height of the support structure 104 may be relatively low at one portion of the support structure configured to receive a component, such as a processing device. Thus, the support structure 104 may be configured to increase stiffness while enabling relatively thin computing device platforms to be formed by receiving components of the computing device into recesses of the support structure 104 created by varying heights of the support structure 104.

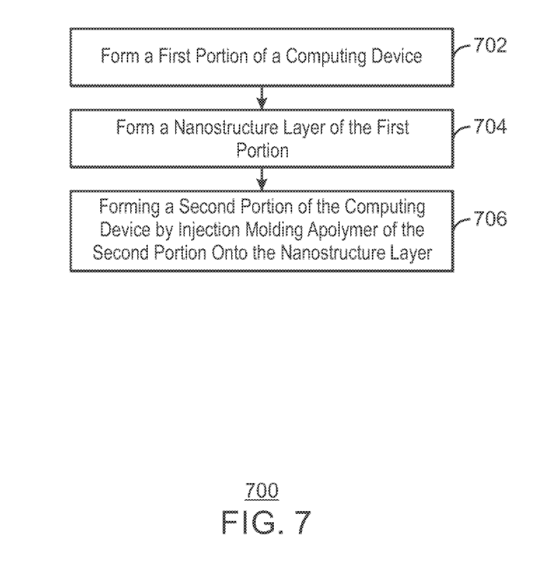

FIG. 7 is a block diagram illustrating a method of forming a cover having a support structure. At block 702, a first portion of a computing device is formed. The first portion may be a cover composed of clad metal, such as the bottom cover 202 of a computing device as discussed above in reference to FIG. 2. A nanostructure layer may be formed at block 704. The nanostructure layer may be a nanostructure oxide applied to an interior surface of the bottom cover as discussed above. The nanostructure layer is configured to receive a polymer of a second portion of a computing device, such as support structure 104 discussed above in reference to FIG. 1. At block 706, the second is formed by injection molding. The second portion may be a support structure, such as the support structure 104 discussed in reference to FIGS. 1-6, and may be composed of a polymer. The polymer may flow into pores of the nanostructured oxide layer during the injection molding process, thereby coupling the polymer, the nanostructured oxide layer, and the bottom cover together.

For example, the injection molding at block 706 includes pressure forcing a molding compound including a low viscosity polymer of the support structure 104 into the pores of the nanostructured oxide layer. The first portion, such as the metal bottom cover 202 of the computing device, is placed in the mold with the nanostructured oxide layer applied to the cover at block 704 facing mold gates. When the mold gates release the molding compound composed of the low viscosity polymer the nanostructure oxide layer receives the molding compound into the pores of the nanostructured oxide layer. The injection molding of the polymer of the second portion enables the polymer to flow into pores of the nanostructure oxide, thereby coupling the first portion to the second portion by mechanical lock.

In embodiments, the method 700 may include forming integration features, such as the integration features 302 discussed above in reference to FIG. 3. The integration features may be simultaneously injection molded onto the nanostructured oxide layer along with the support structure. The simultaneous injection molding may couple both the support structure and the integration features in one step, reducing overall production time.

In embodiments, the integration features include features to assemble other structural parts of a chassis, such as a top cover of the computing device. In embodiments, the integrations features include “cradles” configured to fasten computing device components (for instance a hard drive disk, a fan, a thermal solution, and the like) within a computing device chassis. The integration features may result in reduced component requirements of a computing device such back plane stiffeners of the liquid crystal display modules, and the like.

### EXAMPLE 1

A method of forming covers of a computing device is described herein. The method may include forming a first portion of a computing device, the first portion comprising a metal. The first portion may be a covering means, such as a bottom cover formed of clad metal. In some embodiments, a covering means may include a metal clad aluminum bottom cover of a computing device. A nanostructure layer may be formed on the first portion. The nanostructure layer may be a nanostructure oxide having pores. A second portion of the computing device may be formed by injection molding means. The second portion may be a means for providing support, such as a support structure including an isogrid. The injection molding means may include a mold configured to receive the material of the second portion. The second portion may be composed of a polymer, and the polymer may be received at nanostructure layer and into the pores of the nanostructure layer such that the first portion is coupled to the second portion.

### EXAMPLE 2

An apparatus may include a first portion of a computing device, the first portion composed of a metal. In embodiments, the first portion may be a bottom cover of the computing device, wherein the bottom is composed of a monolithic metal clad material. The bottom cover may have an interior side and a nanostructure layer applied to the first portion at the interior side. The computing device may include a support structure, wherein a second portion of the computing device comprising a polymer is coupled to the first portion by injection molding the second portion onto the nanostructured layer such that the polymer is received at pores of the nanostructure layer.

### EXAMPLE 3

A computing device is described herein. The computing device may include a covering means of a computing device, the covering means may be a bottom cover composed of metal. In some examples, the bottom cover is composed of a monolithic clad metal. The covering means may have an exterior side configured to face outward, and an interior side configured to face inward towards other components of the computing device. The computing device may include a nanostructure layer means applied to the covering means. The nanostructured layer may be a nanostructured oxide layer having pores. The computing device may include a support structure means. The support structure means may be composed of a polymer. The wherein the covering means is coupled to the support structure means by injection molding the polymer of the support structure onto the nanostructure layer means. Specifically, the polymer may be received into the pores of the nanostructured oxide creating a mechanical coupling of the covering means to the support structure means.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the present techniques. The various appearances of “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. A method, comprising:
forming a first portion of a computing device, the first portion comprising a metal;
forming a nanostructure layer of the first portion; and
forming a second portion of the computing device by injection molding, the second portion comprising a polymer coupled to the first portion by injection molding the polymer of the second portion onto the nanostructure layer.

2. The method of claim 1, wherein the nanostructure layer is a nanostructure metal oxide layer having pores, and wherein the polymer is received into the pores during the injection molding.

3. The method of claim 1, wherein the first portion is a bottom cover of the computing device, the bottom cover formed as a clad metal cover, and the second portion is a support structure comprising stiffening ribs.

4. The method of claim 3, wherein the support structure is an isogrid.

5. The method of claim 3, wherein the support structure defines a hole configured to receive a fastener.

6. The method of claim 1, comprising:
forming integration features, the integration features to join the first portion to additional components of the computing device; and
coupling the integration features to the first portion by injection molding simultaneously with the coupling of the first portion to the second portion.

7. The method of claim 1, wherein the computing device is an all-in-one (AIO) computing device.

8. The method of claim 1, wherein coupling of the first portion to the second portion increases the stiffness of the first portion.

9. An apparatus, comprising:
a first portion of a computing device, the first portion comprising a metal;
a nanostructure layer applied to the first portion; and
a second portion of the computing device, the second portion comprising a polymer, wherein the first portion is coupled to the second portion by injection molding the polymer of the second portion onto the nanostructure layer.

10. The apparatus of claim 9, wherein the nanostructure layer is a nanostructure metal oxide layer having pores, and wherein the polymer is received into the pores during the injection molding.

11. The apparatus of claim 9, wherein the first portion is a bottom cover of the computing device and the second portion is a support structure comprising stiffening ribs.

12. The apparatus of claim 11, wherein the support structure is an isogrid.

13. The apparatus of claim 11, wherein the support structure defines a hole configured to receive a fastener.

14. The apparatus of claim 9, comprising integration features to join the first portion to additional components of the computing device, wherein the integration features are coupled to the first portion by injection molding simultaneously with the coupling of the first portion to the second portion.

15. The apparatus of claim 9, wherein the computing device is an all-in-one (AIO) computing device.

16. The apparatus of claim 9, wherein the coupling of the first portion to the second portion is to increase the stiffness of the first portion.

17. A computing device, comprising:
a cover of a computing device, the cover comprising a metal;
a nanostructure layer applied to the cover; and
a support structure of the computing device, the support structure comprising a polymer, wherein the cover is coupled to the support structure by injection molding the polymer of the support structure onto the nanostructure layer.

18. The computing device of claim 17, wherein the nanostructure layer is a nanostructure metal oxide layer having pores, and wherein the polymer is received into the pores during the injection molding.

19. The computing device of claim 17, wherein the cover is a bottom cover of the computing device and the support structure comprises stiffening ribs.

20. The computing device of claim 17, wherein the support structure is an isogrid.

21. The computing device of claim 17, wherein the support structure defines a hole configured to receive a fastener.

22. The computing device of claim 17, comprising integration features to join the cover to additional components of the computing device, wherein the integration features are to be coupled to the cover by injection molding simultaneously with the coupling of the cover to the support structure.

23. The computing device of claim 17, wherein the computing device is an all-in-one (AIO) computing device.

24. The computing device of claim 17, wherein the coupling of the cover to the support structure is to increase the stiffness of the cover.
